(19) United States
(12) Patent Application Publication
(10) Pub. No.: US 2012/0018198 A1
(43) Pub. Date: Jan. 26, 2012

(54) ELECTRONIC COMPONENT AND PRINTED WIRING BOARD

(75) Inventors: Toshiki FURUTANI, Ogaki-shi (JP); Minetaka Oyama, Ogaki-shi (JP); Daiki Komatsu, Ogaki-shi (JP); Koichi Tsunoda, Ogaki-shi (JP); Toshimasa Yano, Ogaki-shi (JP)

(73) Assignee: IBIDEN CO., LTD., Ogaki-shi (JP)

(21) Appl. No.: 13/074,377

(22) Filed: Mar. 29, 2011

Related U.S. Application Data
(60) Provisional application No. 61/319,035, filed on Mar. 30, 2010.

(51) Int. Cl. H05K 1/03; H05K 3/00; H05K 1/11

(52) U.S. Cl. 174/255; 174/258; 29/829

(57) ABSTRACT

An electronic component including a substrate having a surface and one or more trench portions opening on the surface, a capacitor portion having a lower electrode formed on the surface of the substrate and on the wall surface of the trench portion, a dielectric layer formed on the lower electrode, and an upper electrode formed on the dielectric layer, a resin filler filling the space inside the trench portion lined by the upper electrode, an insulation layer formed on the surface of the substrate, a conductive portion formed on the insulation layer and positioned to cover the trench portion, and a via conductor connecting the conductive portion and one of the lower electrode and the upper electrode.

### CROSS-REFERENCE TO RELATED APPLICATIONS

The present application claims the benefits of priority to U.S. Application No. 61/319,035, filed Mar. 30, 2010. The contents of that application are incorporated herein by reference in their entirety.

### BACKGROUND OF THE INVENTION

1. Field of the Invention

The present invention relates to an electronic component with a capacitor section to be built into a printed wiring board, and to a printed wiring board with a built-in electronic component.

2. Discussion of the Background

In Japanese Laid-Open Patent Publication 2008-227177, a method for manufacturing an electronic component to be mounted between a semiconductor element and a board substrate is described. Such a method for manufacturing an electronic component is as follows: (1) a step for embedding a signal-via conductor in an inorganic substrate; (2) a step for forming a coupling capacitor on a main surface of the inorganic substrate so that the coupling capacitor is connected to the embedded signal-via conductor by covering it; (3) a step for forming a signal pad on the side of an active element to be electrically connected to the coupling capacitor; and (4) a step for forming a signal pad on the board side to be electrically connected to the board substrate. The contents of this publication are incorporated herein by reference in their entirety.

### SUMMARY OF THE INVENTION

According to one aspect of the present invention, an electronic component includes a substrate having a surface and one or more trench portions opening on the surface, a capacitor portion having a lower electrode formed on the surface of the substrate and on the wall surface of the trench portion, a dielectric layer formed on the lower electrode, and an upper electrode formed on the dielectric layer, a resin filler filling the space inside the trench portion lined by the upper electrode, an insulation layer formed on the surface of the substrate, a conductive portion formed on the insulation layer and positioned to cover the trench portion, and a via conductor connecting the conductive portion and either the lower electrode or the upper electrode.

According to another aspect of the present invention, a method for manufacturing an electronic component includes forming one or more trench portions in a substrate such that the trench portion has the opening on a surface of the substrate, forming on the surface of the substrate and the wall portion of the trench portion a capacitor portion having a lower electrode, a dielectric layer and an upper electrode, filling a resin filler in the space inside the trench portion lined by the upper electrode, forming an insulation layer on the surface of the substrate, forming a conductive portion on the insulation layer such that the conductive portion covers the trench portion, and forming a via conductor in the insulation layer such that the conductive portion is connected to either the lower electrode or the upper electrode.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1(A) is a plan view of an Si capacitor according to the first embodiment of the present invention;

FIG. 1(B) is a cross-sectional view taken from the (b-b) line in FIG. 1(A);

FIG. 1(C) is an enlarged cross-sectional view showing part of FIG. 1(B);

FIG. 2(A) shows a (−) electrode pad in FIG. 1(A);

FIG. 2(B) is a cross-sectional view taken from the (b′-b′) line in FIG. 2(A);

FIG. 2(C) is an enlarged cross-sectional view showing part of FIG. 2(B);

FIG. 2(D) is an enlarged cross-sectional view showing part of FIG. 2(C);

FIG. 3(A) shows a (+) electrode pad in FIG. 1(A);

FIG. 3(B) is a cross-sectional view taken from the (b″-b″) line in FIG. 3(A);

FIG. 3(C) is an enlarged cross-sectional view showing part of FIG. 3(B);

FIG. 3(D) is an enlarged cross-sectional view showing part of FIG. 3(C);

FIG. 4 are steps for manufacturing an Si capacitor according to the first embodiment;

FIG. 5 are steps for manufacturing an Si capacitor according to the first embodiment;

FIG. 6 are steps for manufacturing an Si capacitor according to the first embodiment;

FIG. 7 are steps for manufacturing an Si capacitor according to the first embodiment;

FIG. 8 are steps for manufacturing an Si capacitor according to the first embodiment;

FIG. 9 are steps for manufacturing an Si capacitor according to the first embodiment;

FIG. 10 are steps for manufacturing an Si capacitor according to the first embodiment;

FIG. 11 are steps for manufacturing an Si capacitor according to the first embodiment;

FIG. 12 is a step for manufacturing an Si capacitor according to the first embodiment;

FIG. 13 is a step for manufacturing an Si capacitor according to the first embodiment;

FIG. 14 is a step for manufacturing an Si capacitor according to the first embodiment;

FIG. 15(A) is a cross-sectional view of a printed wiring board according to the first embodiment;

FIG. 15(B) is a cross-sectional view of a printed wiring board with a mounted IC chip;

FIG. 16(A) is a cross-sectional view of a printed wiring board according to the second embodiment;

FIG. 16(B) is a cross-sectional view of a printed wiring board with a mounted IC chip; and

FIG. 17 is a cross-sectional view of an electronic device according to the third embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

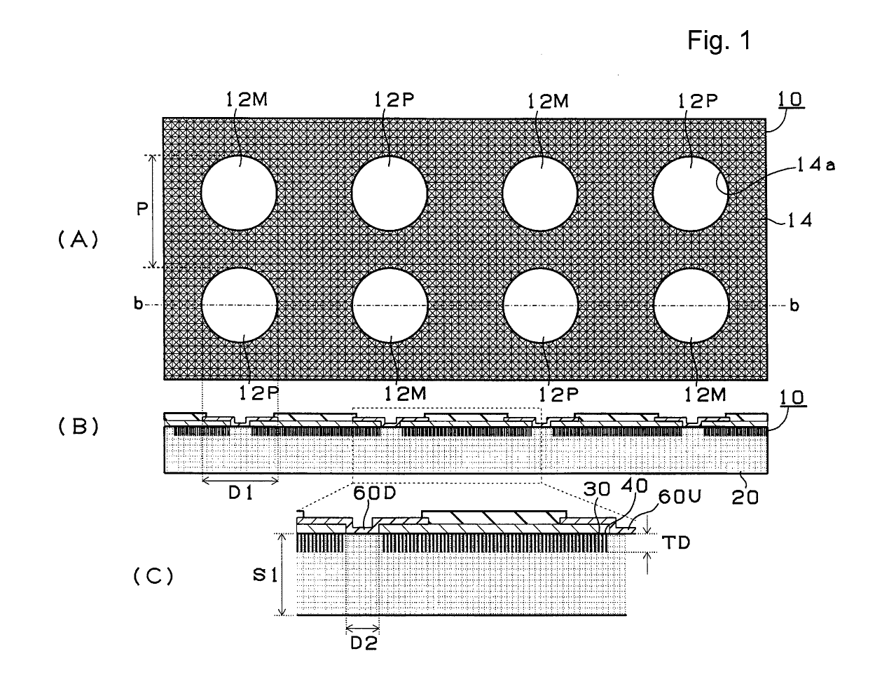

A capacitor component structuring an electronic component according to the first embodiment of the present invention is described with reference to FIGS. 1-3.

FIG. 1(A) is a plan view of capacitor component 10. Primarily, capacitor component 10 has a substrate and a capacitor section formed on the substrate. As for the substrate, any one of silicon, glass or ceramic having excellent flatness features is preferred. Insulation layer 14 with multiple openings (14a) is formed on an upper surface of capacitor component 10. Electrode pads (12P, 12M) are exposed through their respective openings (14a). In the present embodiment, electrode pad (12M) is connected to a lower electrode, and electrode pad (12P) is connected to an upper electrode. Such electrode pads (12P, 12M) are alternately lined up in a matrix format. Pitch (P) between electrode pads is set at 500 μm.

FIG. 1(B) is a cross-sectional view taken from the (b-b) line in FIG. 1(A), and FIG. 1(C) is an enlarged cross-sectional view showing part of FIG. 1(B). Trenches (or recessed portions) 30 are formed in the first-surface (upper-surface) side of substrate 20, and capacitor section 40 is formed in trenches 30. For example, thickness (S1) of substrate 20 is set at 300 μm and depth (TD) of trenches 30 is set at 70 μm. Electrodes (12P, 12M) are formed on the upper surface of Si substrate 20. External diameter (D1) of electrode pads (12P, 12M) is set at 200 μm, and diameter (D2) of via conductors (60D, 60U) is set at 50 μm.

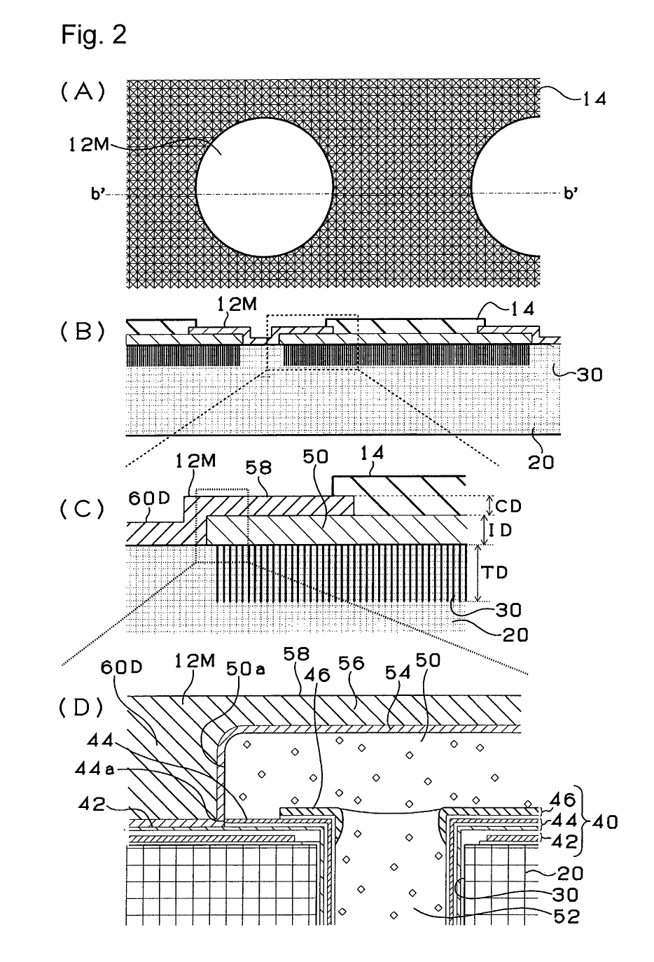

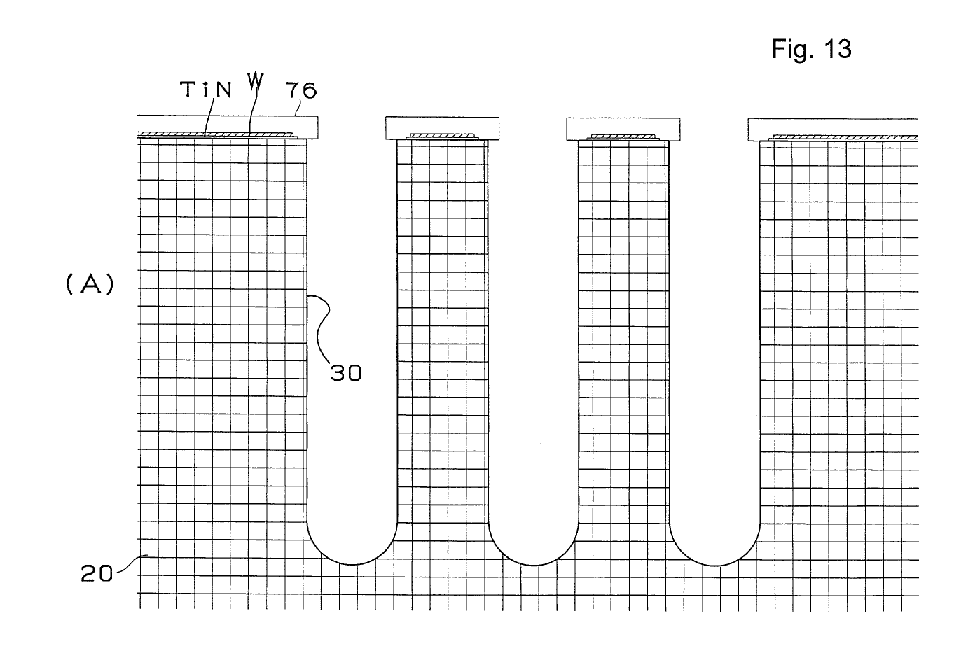

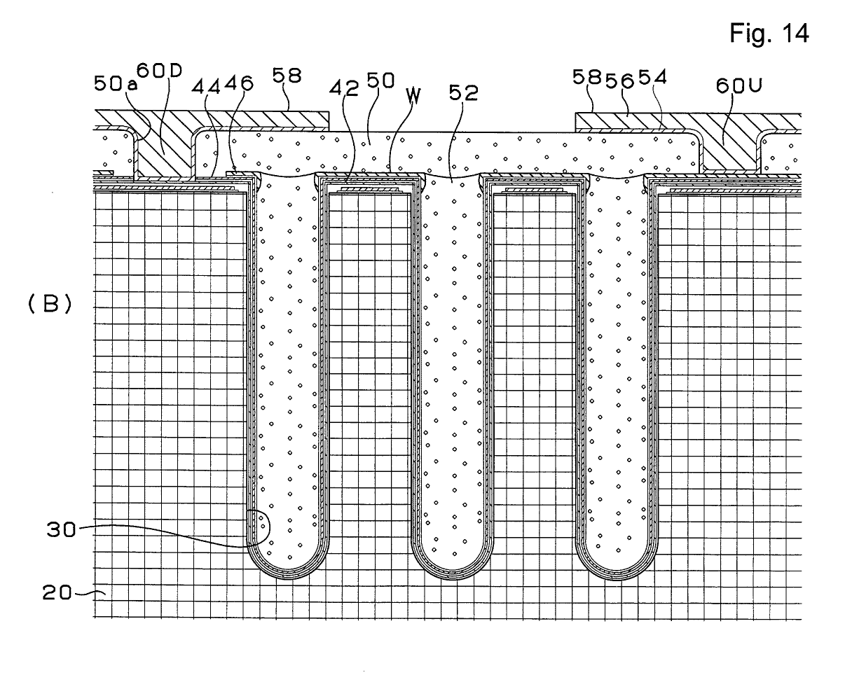

FIG. 2(A) shows electrode pad (12M) in FIG. 1(A), FIG. 2(B) is a cross-sectional view taken from the (b′-b′) line in FIG. 2(A), FIG. 2(C) is an enlarged cross-sectional view showing part of FIG. 2(B), and FIG. 2(D) is an enlarged cross-sectional view showing part of FIG. 2(C). Only the upper portion of trench 30 is shown in FIG. 2(D), but the entire structure of a trench is shown in FIGS. 13 and 14.

As shown in FIG. 2(C), insulation layer 50 is formed on the first surface of the substrate, including trenches. Electrode pad (12M) is formed on insulation layer 50. Electrode pad (12M) is connected to a lower electrode by via conductor (60D). More specifically, it is connected to a lower electrode positioned in a region where trenches are not formed (a flat portion of the substrate). Then, electrode pad (12M) is formed to cover the resin filler in multiple trenches. Thickness (ID) of insulation layer 50 is set at 10 μm, and thickness (CD) of land portion 58 of electrode pad (12M) is set at 10 μm.

As shown in FIG. 2(D), capacitor section 40 is formed on the first surface (upper surface) of substrate 20 and on the wall surfaces of trenches 30. Capacitor section 40 is formed with lower electrode 42 made of TiN/W/TiN, dielectric layer 44 made of AlO/ZrSiO and upper electrode 46 made of TiN/W. In trenches 30, however, lower electrode 42 of capacitor section 40 is made of TiN, and upper electrode 46 is made of TiN/Ti. In a trench, space lined by the upper electrode is filled with resin filler 52, and insulation layer 50 is formed on the substrate to cover capacitor section 40. In insulation layer 50, opening (50a) exposing the lower electrode is formed. Via conductor (60D) is formed in opening (50a). Electrode pad (12M) and the lower electrode are connected by via conductor (60D). Here, via conductor (60D) and upper electrode 46 are insulated. Namely, insulation layer 50 exists between via conductor (60D) and upper electrode 46.

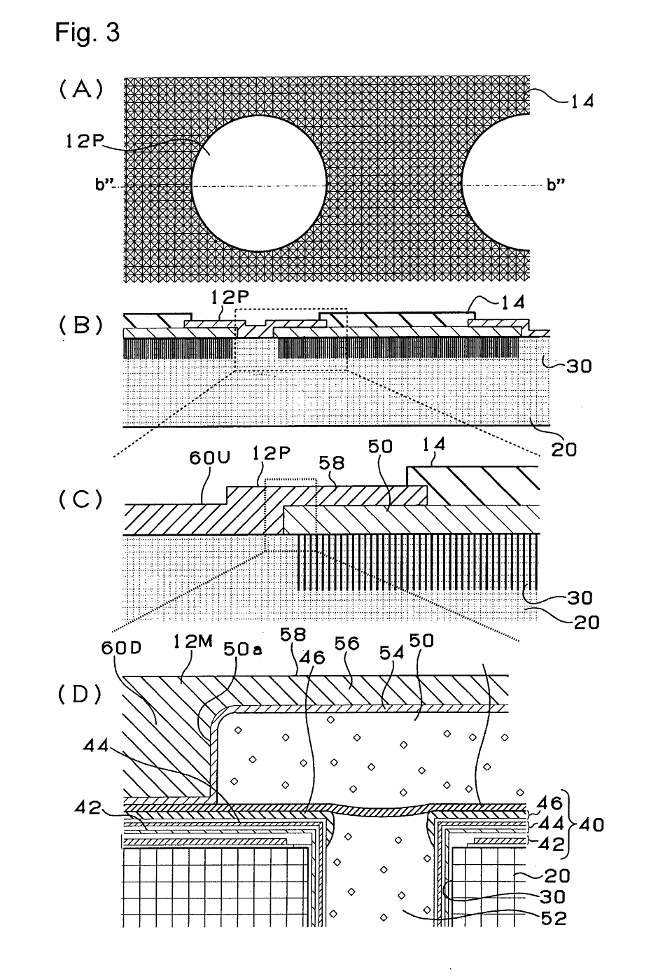

FIG. 3(A) shows electrode pad (12P) in FIG. 1(A), FIG. 3(B) is a cross-sectional view taken from the (b″-b″) line in FIG. 3(A), FIG. 3(C) is an enlarged cross-sectional view showing part of FIG. 3(B), and FIG. 3(D) is an enlarged cross-sectional view showing part of FIG. 3(C). Only the upper portion of trench 30 is shown in FIG. 3(D), but the entire structure of a trench is shown in FIGS. 13 and 14.

As shown in FIG. 3(C), electrode pad (12P) is formed on insulation layer 50. Electrode pad (12M) is connected to an upper electrode by means of via conductor (60U). More specifically, it is connected to an upper electrode positioned in a region where trenches are not formed (a flat portion of the substrate), and electrode pad (12M) is formed to cover the resin filler in multiple trenches. As shown in FIG. 3(D), opening (50b) exposing an upper electrode is formed in insulation layer 50. Via conductor (60U) is formed in opening (50b). Electrode pad (12P) and the upper electrode are connected by via conductor (60U).

In capacitor component 10 of the first embodiment, capacitor section 40, which is formed with lower electrode 42, dielectric layer 44 and upper electrode 46, is formed on the surface (first surface) of substrate 20 as well as on the wall surfaces of trenches 30. Thus, the actual area between opposing electrodes is enlarged and higher capacitance is achieved. In addition, since resin filler 52 is filled in trenches 30, stress generated on the side walls of trenches 30 is absorbed by resin filler 52. Therefore, cracks occurring on the side walls of trenches 30 are suppressed even when trenches are formed at a narrow pitch to increase capacitance.

In capacitor 10 of the first embodiment, since resin insulation layer 50 is arranged on substrate 20, stress generated in substrate 20 is mitigated by insulation layer 50 when the capacitor is accommodated in a printed wiring board.

In capacitor 10 of the first embodiment, land portions 58 of electrode pads (12P, 12M) cover multiple trenches 30 by means of resin insulation layer 50. Accordingly, when resin filler 52 in trenches 30 expands due to heat, such expansion is suppressed by land portions 58 positioned over the filler. As a result, if stress is exerted on via conductors (60U, 60D) caused by thermal expansion of insulation layer 50, for example, such stress is mitigated, and that line breakage or the like of via conductors is suppressed.

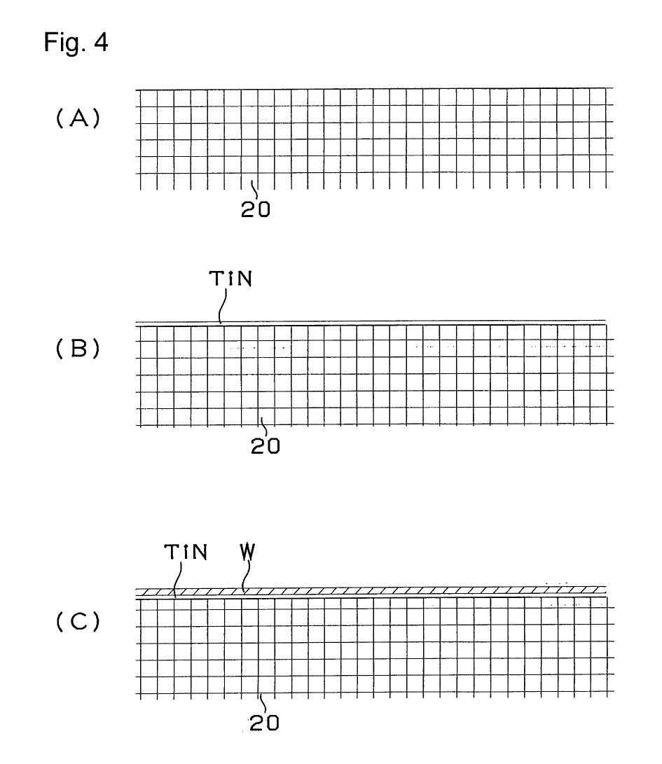

In the following, steps for manufacturing capacitor component 10 are described with reference to FIGS. 4-14.

(1) Si wafer 20 with an approximate thickness of 300 μm is prepared (FIG. 4(A)).

(2) TiN film with a thickness of 10 nm is formed on Si wafer 20 by sputtering

(FIG. 1(B)).

(3) Next, W film with a thickness of 100 nm is formed on the TiN film by sputtering (FIG. 4(C)).

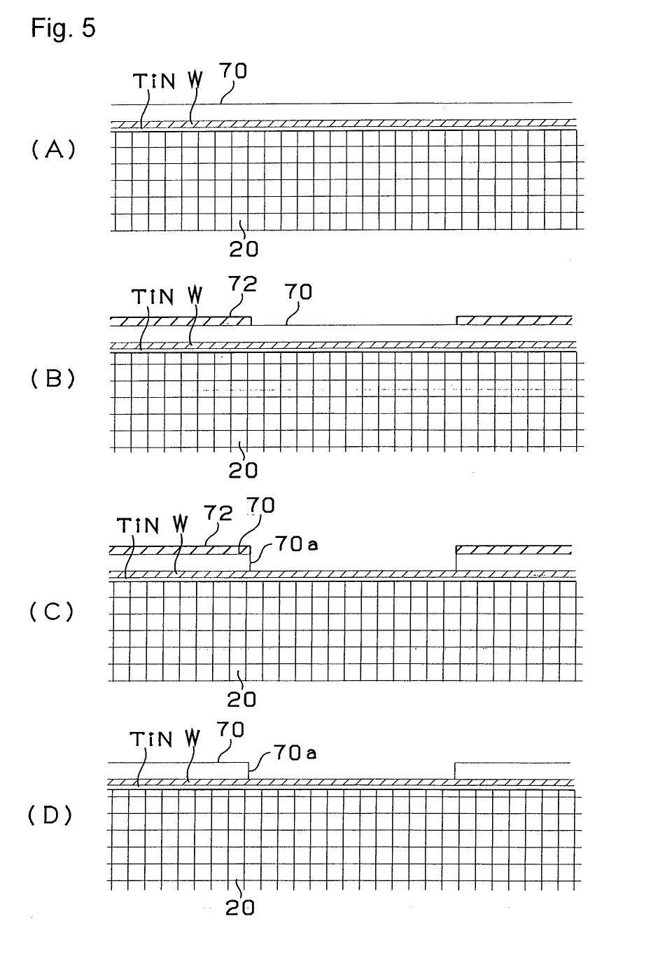

(4) Hard mask 70 made of SiO₂ is formed on the W film by plasma CVD using TEOS (tetraethoxysilane) (FIG. 5(A)).

(5) A positive resist is applied on hard mask 70, which is then exposed to light and developed (TMAH) to form resist layer 72 with a predetermined pattern (FIG. 5(B)).

(6) Opening portion (70a) is formed by RIE (reactive ion etching) in hard mask 70 where resist layer 72 is not formed (FIG. 5(C)), and W film is exposed. The resist layer on hard mask 70 is removed (FIG. 5(D)).

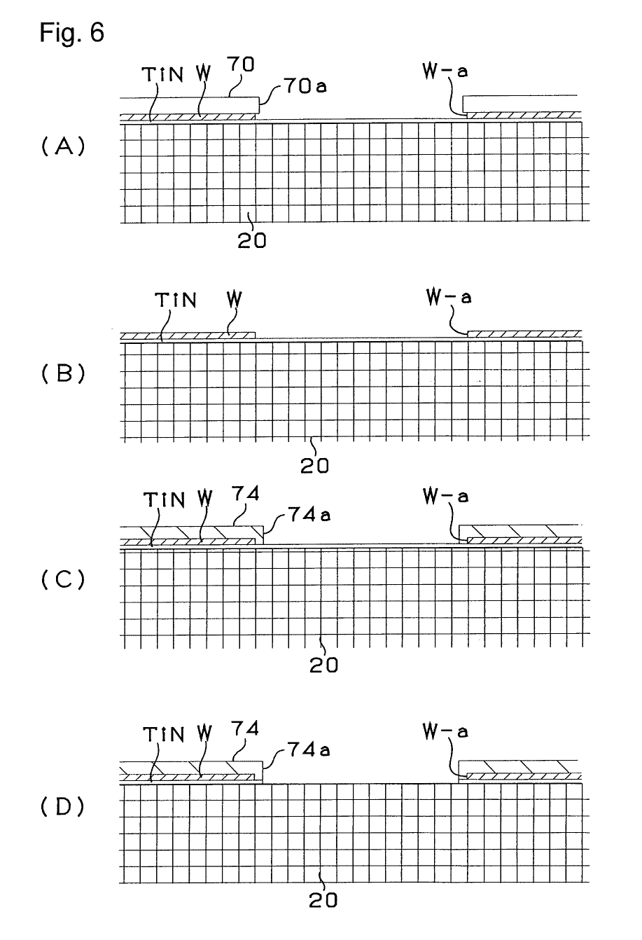

(7) The W film exposed through opening portion (70a) in hard mask 70 is removed by etching, and opening (W-a) is formed in W film (FIG. 6(A)). Then, hard mask 70 is removed (FIG. 6(B)).

(8) Resist 74 with opening (74a) is formed on the W layer (FIG. 6(C)). During that time, opening (74a) in resist 74 is formed by being extended onto the TiN layer so that the periphery of opening (W-a) is embedded.

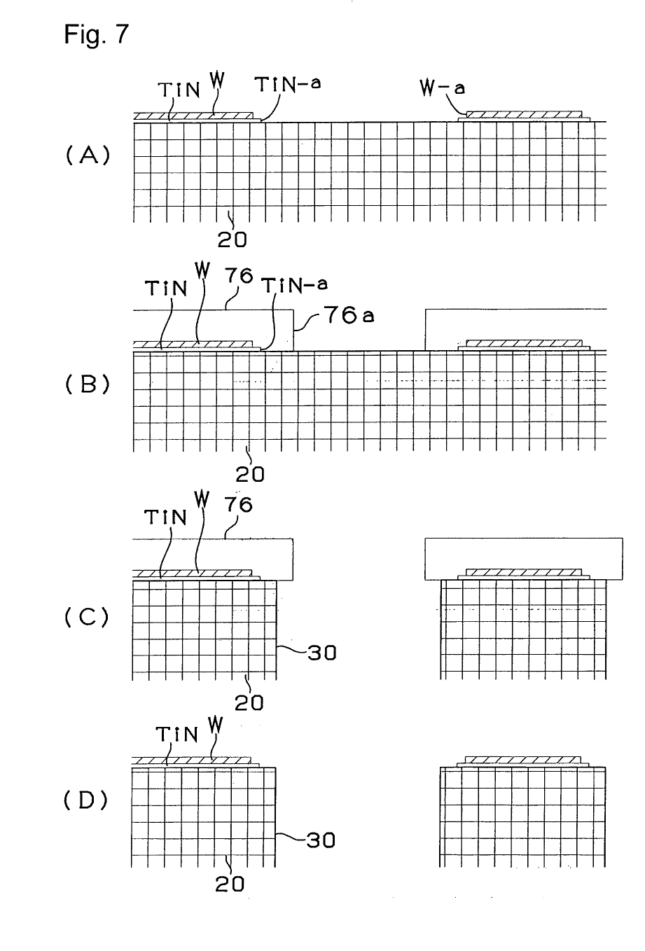

(9) The TiN layer exposed through opening (74a) in resist 74 is removed by etching (FIG. 6(D)). Then, resist 74 is removed (FIG. 7(A)). Here, end portion (TiN-a) of the TiN film is extended inward beyond opening (W-a) of the W film. Namely, the lower electrode having the TiN film and W film is formed to have a step form. Accordingly, the surface area of the edge portion of the lower electrode increases, and stress concentrated in such a portion is mitigated. As a result, cracks are suppressed from occurring inside the later-described dielectric layer.

(10) Spacer 76 made of SiO2 and having opening (76a) is formed on the W film by plasma CVD using TEOS (tetraethoxysilane) (FIG. 7(B)). Here, opening (76a) is formed inside end portion (TiN-a) of the TiN film.

(11) Trench 30 is formed in Si wafer 20 by Si etching (FIG. 7(C)); the entire structure of trench 30 is shown in FIG. 13. Then, spacer 76 is removed by etching using hydrofluoric acid (FIG. 7(D)).

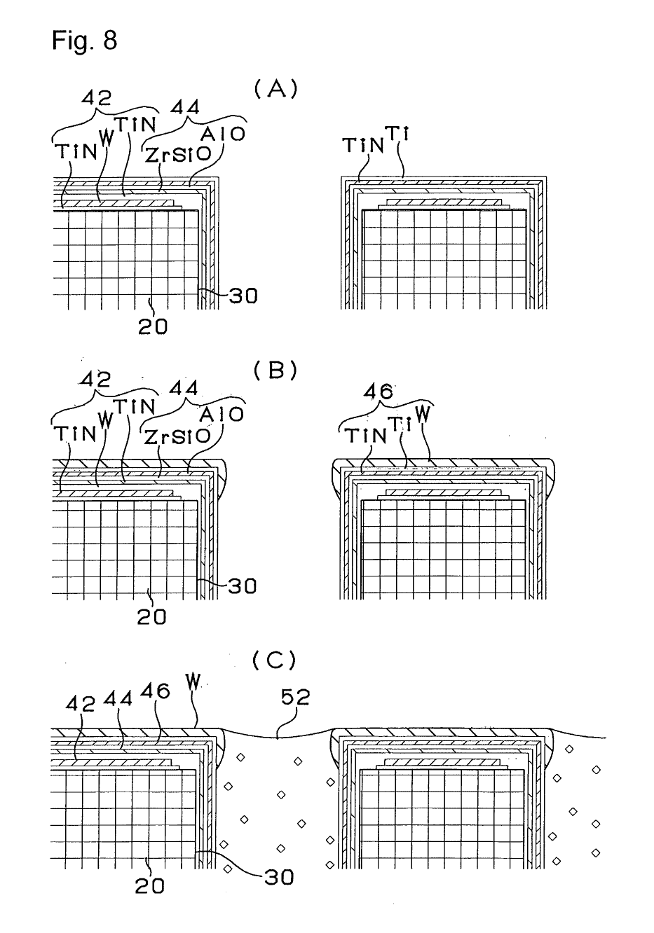

(12) On the upper surface of Si wafer 20 and in trench 30, 30 nm-thick TiN film is further formed by CVD on the TiN film and W film already formed on Si wafer 20. Lower electrode 42 made of TiN/W/TiN is completed. Next, 12 nm-thick ZrSiO film is formed on lower electrode 42 by an ALD (Atomic Layer Deposition) process, and then 1 nm-thick AlO film is formed by ALD. Accordingly, dielectric layer 44 made of ZrSiO/AlO is completed. Furthermore, 20 nm-thick TiN film is formed by CVD on dielectric layer 44, and 10 nm-thick Ti film is formed by CVD (FIG. 8(A)).

(13) On the TiN film and Ti film already formed by sputtering, a 100 nm-thick W layer is formed. Accordingly, upper electrode 46 made of TiN/Ti/W is formed and capacitor section 40 is completed (FIG. 8(B)). As described above with reference to FIG. 2(D), capacitor section 40 on the upper surface of Si wafer 20 is formed with lower electrode 42 made of TiN/W/TiN and upper electrode 46 made of TiN/Ti/W. Capacitor section 40 in trench 30 is formed with lower electrode 42 of capacitor section 40 made of TiN and upper electrode 46 made of TiN/Ti. Here, the W layer, the outermost layer of the upper electrode, is formed thicker in the edge portion of the first surface of Si wafer 20 and trench 30 so as to make a round shape at the edge portion. By doing so, stress is prevented from being concentrated in the later-described resin filler and insulation layer.

(14) Resin filler 52 is filled in trench 30 (FIG. 8(C)). Here, photosensitive resin (for example, brand name “WPR” made by JSR Corporation) is applied, and then the resin is exposed to light, developed and thermally cured to fill resin filler 52.

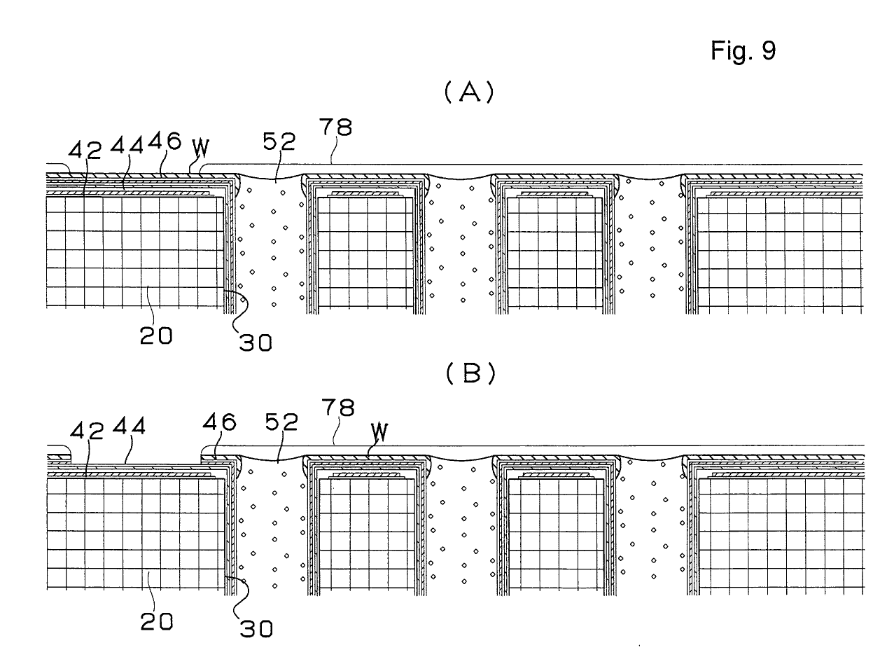

(15) A resist solution is applied, exposed to light and developed (TMAH). Accordingly, resist 78 with opening (78a) is formed (FIG. 9(A)).

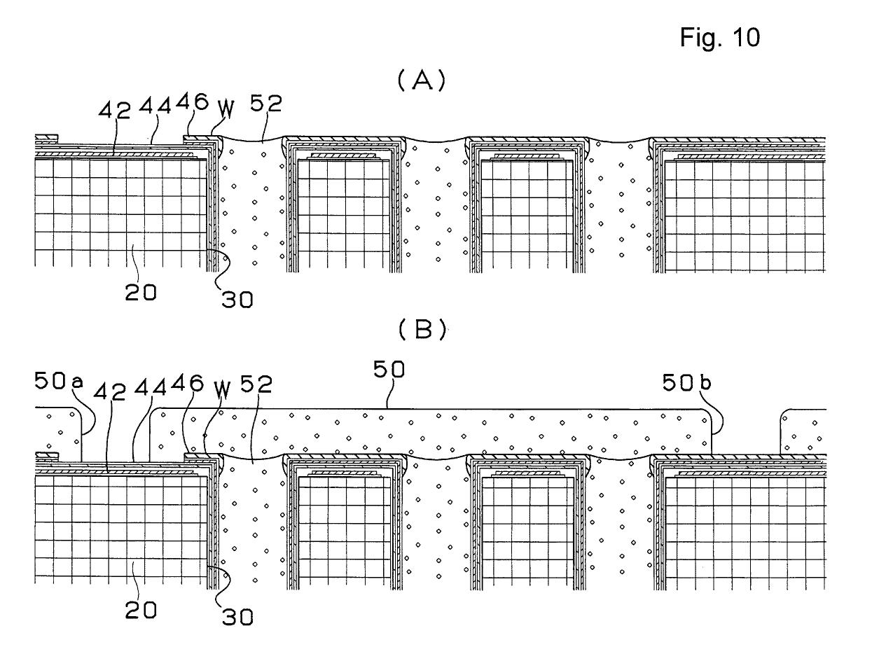

(16) The TiN/Ti/W film which forms upper electrode 46 and is positioned in opening (78a) in resist 78 is removed by wet etching using an H2O2+KOH solution to expose dielectric layer 44 (FIG. 9(B)). Then, resist 78 is removed (FIG. 10(A)).

(17) Insulation layer 50 is formed, having opening (50a) for forming electrode pad (12M) and opening (50b) for forming electrode pad (12P) (FIG. 10(B)). Here, the same photosensitive resin which is used for resin filler is applied, exposed to light and developed. Then, the resin is thermally cured.

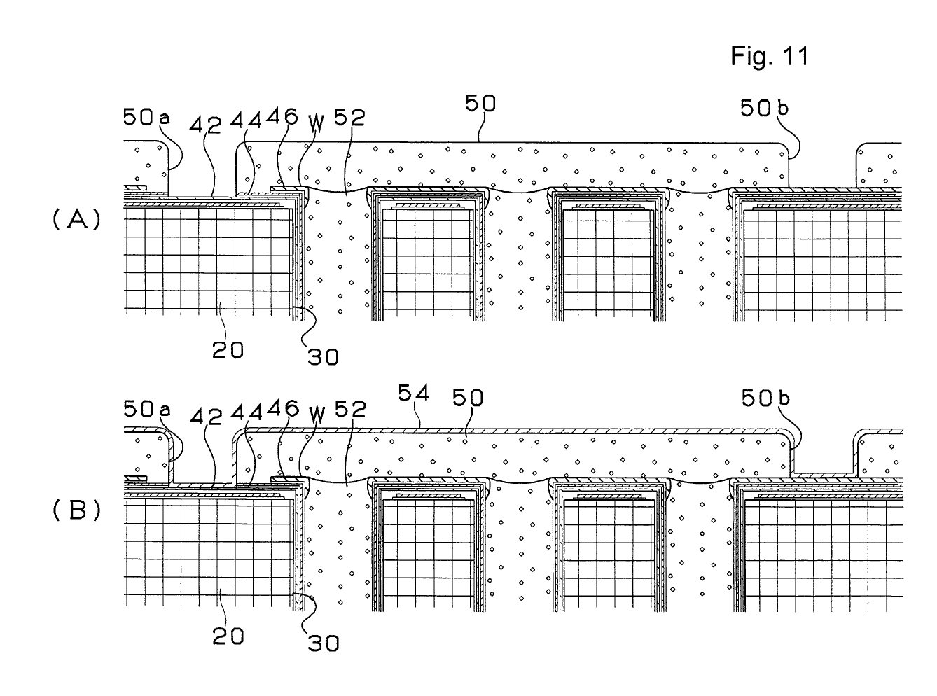

(18) Dielectric layer 44 exposed through opening (50a) is removed by wet etching and by diluted HF treatment (FIG. 11(A)). In the first embodiment, insulation layer 50 works as an etching resist.

(19) By TiN/Ti/Cu sputtering, seed layer 54 is formed with TiN (15 nm)/Ti (30 nm)/Cu (60 nm) on the surface of insulation layer 50 and in openings (50a, 50b) (FIG. 11(B)).

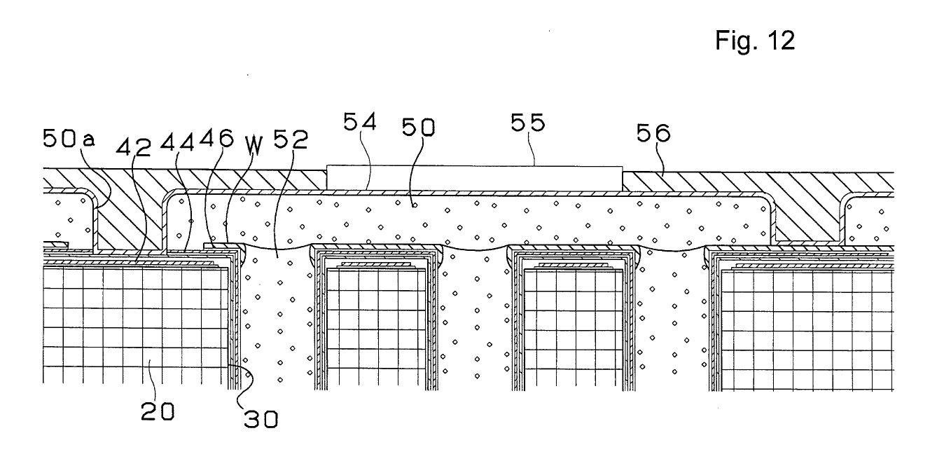

(20) Plating resist 55 with a predetermined pattern is formed, and electricity passes through seed layer 54 to form electrolytic copper-plated film 56 in portions where plating resist 55 is not formed (FIG. 12).

(21) By removing the plating resist using a chemical solution, and by etching to dissolve seed layer 54 under the plating resist, via conductors (60U, 60D) and land portions 58 (electrode pads) are formed (FIG. 14). Accordingly, capacitor component 10 is completed. Here, as described above with reference to FIG. 1(B), it is also preferred to form insulative film 14 (such as solder-resist film) on insulation layer 50.

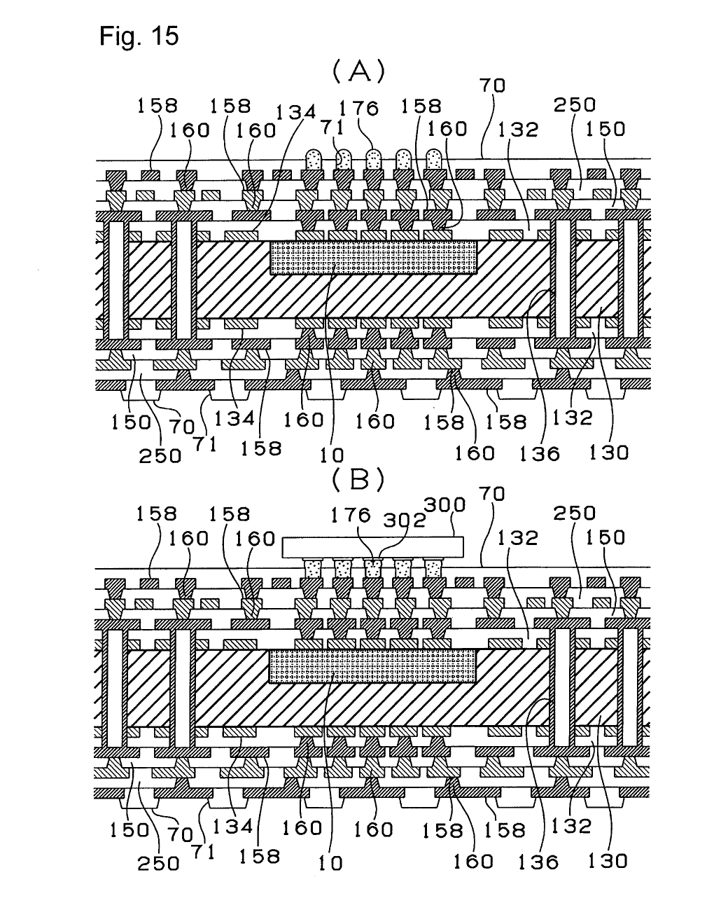

A printed wiring board with built-in capacitor component 10 of the first embodiment is described with reference to FIG. 15. FIG. 15 show an example where capacitor component 10 is accommodated in core substrate 130. FIG. 15(A) is a cross-sectional view of a printed wiring board according to the first embodiment. Core substrate 130 which accommodates Si capacitor 10 is formed by laminating prepreg. For example, B-stage prepreg, which is formed by impregnating glass fiber, aramid fiber or non-woven fabric with resin such as epoxy resin, polyimide resin, bismaleimide triazine resin or fluoride resin (polytetrafluoroethylene or the like), is laminated and integrated by thermal pressing to form core substrate 130.

Circuit patterns 134 are formed on the upper and lower surfaces of core substrate 130. Interlayer resin insulation layers 132 containing circuit patterns 158 and via conductors 160 are laminated as upper layers of core substrate 130. For interlayer resin insulation layers, thermosetting resin or thermoplastic resin without core material, or a composite of thermosetting resin and thermoplastic resin may be used. Moreover, through-hole conductors 136 which connect circuit patterns on the upper and lower surfaces of core substrate 130 are formed.

As upper layers of interlayer resin insulation layers 132, interlayer resin insulation layers 150 are formed containing circuit patterns 158 and via conductors 160. Moreover, as upper layers of interlayer resin insulation layers 150, interlayer resin insulation layers 250 are formed containing circuit patterns 158 and via conductors 160. As upper layers of interlayer resin insulation layers 250, solder-resist layers 70 are formed, and solder bumps 176 are formed in openings 71 of upper solder-resist layer 70.

FIG. 15(B) is a view showing the above printed wiring board with mounted IC chip 300. IC chip 300 is mounted on solder bumps 176 by means of pads 302.

Since Si capacitor 10 containing a high-capacitance capacitor section is accommodated directly under mounted IC chip 300 in a printed wiring board according to the first embodiment, the distance is reduced between the IC chip and the capacitor section, and power supply to the IC chip is intensified. Therefore, even if an increase in power consumption occurs instantaneously in a high-frequency IC chip, the voltage supply does not fall off, thus allowing the IC chip to continue operating properly. In such a case, it is preferred to form through-hole conductors in the capacitor component. In doing so, voltage is supplied to the IC chip through such through-hole conductors, and the voltage-supply circuit becomes shorter.

### Second Embodiment

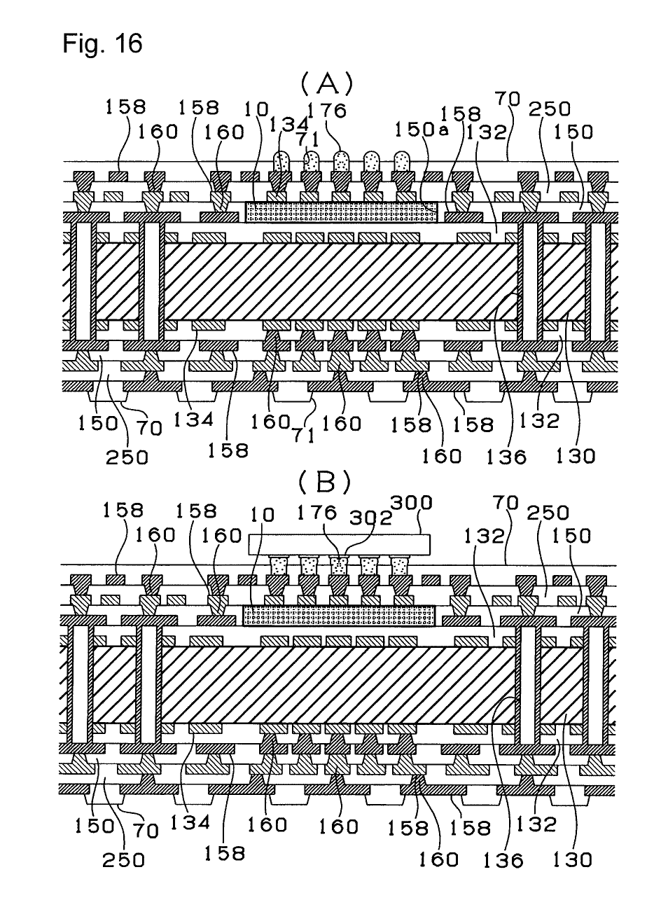

Printed wiring board with built-in Si capacitor 10 according to the second embodiment is described with reference to FIG. 16. FIG. 16 show an example in which capacitor component 10 is accommodated in an interlayer resin insulation layer.

FIG. 16(A) is a cross-sectional view of a printed wiring board according to the second embodiment. Circuit patterns 134 are formed on upper and lower surfaces of core substrate 130, and interlayer resin insulation layers 132 containing circuit patterns 158 and via conductors 160 are laminated. Then, through holes 136 are formed to penetrate through core substrate 130, upper interlayer resin insulation layer 132 and lower interlayer resin insulation layer 132. As an upper layer of upper interlayer resin insulation layer 132, interlayer resin insulation layer 150 is formed to accommodate Si capacitor 10 in opening (150a). In upper interlayer resin insulation layer 150, circuit patterns 158 and via conductors 160 are formed. In the same manner, in lower interlayer resin insulation layer 150, circuit patterns 158 and via conductors 160 are also formed. Moreover, as upper layers of interlayer resin insulation layers 150, interlayer resin insulation layers 250 are formed containing circuit patterns 158 and via conductors 160. As upper layers of interlayer resin insulation layers 250, solder-resist layers 70 are formed. Solder bumps 176 are formed in openings 71 of upper solder-resist layer 70.

FIG. 16(B) is a view showing IC chip 300 mounted on the above printed wiring board. IC chip 300 is mounted on solder bumps 176 by means of pads 302.

In the printed wiring board according to the second embodiment, since Si capacitor 10 containing a high-capacitance capacitor section is accommodated directly under mounted IC chip 300, the distance is reduced between the IC chip and the capacitor section, and power supply to the IC chip is intensified. Therefore, even if an increase in power consumption occurs instantaneously in a high-frequency IC chip, the voltage supply does not fall off, thus allowing the IC chip to continue operating properly.

### Third Embodiment

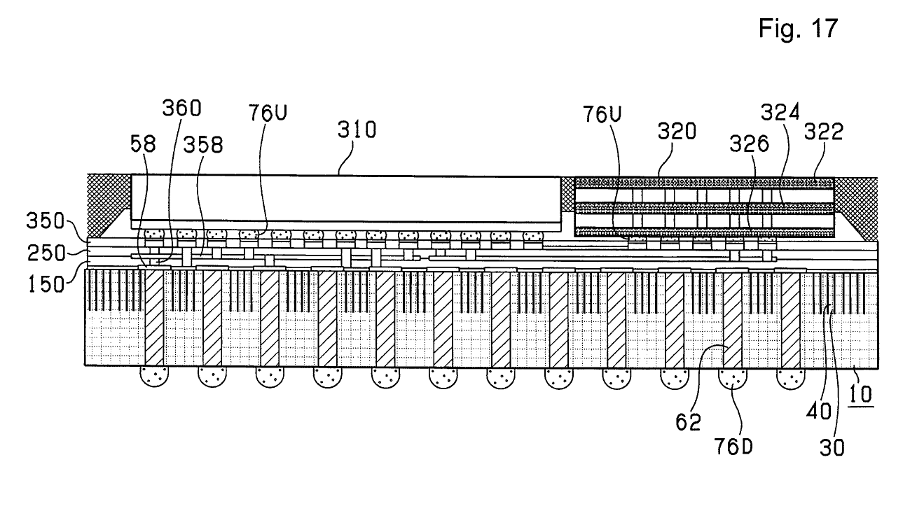

In the present embodiment, an electronic component is used as an interposer positioned between a printed wiring board and an IC chip. Its details are described with reference to FIG. 17.

Interposer 10 as the electronic component in the third embodiment has through-hole conductors 62 to connect an upper surface (first surface) and a lower surface (second surface) of the substrate. Solder bumps 76 are formed on the lower-surface side. The first-surface side and the second-surface side of Si capacitor 10 are connected by the shortest possible route by using through-hole conductors 62.

Interlayer resin insulation layers (150, 250, 350) and circuit patterns 358 are alternately arranged on the upper surface of interposer 10. Interlayer circuit patterns are connected by via conductors 360. Solder bumps (76U) are positioned on uppermost circuit patterns 358. By means of solder bumps (76U), CPU chip 310 is mounted on the left of the drawing, and memory unit 320 is mounted on the right of the drawing. Memory unit 320 is formed with memory chips (322, 324, 326).

In the third embodiment, since IC chip 310 is mounted directly on interposer 10 containing high-capacitance capacitor section 40, the distance is reduced between IC chip 310 and capacitor section 40, and the power supply to the IC chip is intensified. Accordingly, even if an increase in power consumption occurs instantaneously in a high-frequency IC chip, the voltage supply does not fall off, thus allowing the IC chip to continue operating properly.

An electronic component according to an embodiment of the present invention has the following: a substrate with a first surface and having a trench portion (a recessed portion) which opens on the first surface; a capacitor section containing a lower electrode formed on the first surface of the substrate and on the wall surface of the trench portion, a dielectric layer formed on the lower electrode, and an upper electrode formed on the dielectric layer; resin filler filled in the space which is inside the trench portion and is lined by the upper electrode; an insulation layer formed on the first surface of the substrate; a conductive portion formed on the insulation layer; and a via conductor connecting either the lower electrode or the upper electrode and the conductive portion. In such an electronic component, the conductive portion is arranged to cover the trench portion.

In the electronic component above, since a capacitor section made up of a lower electrode, a dielectric layer and an upper electrode is formed on the wall surfaces of trench portions in the substrate, the actual area between the opposing electrodes is enlarged and higher capacitance is achieved. In addition, since resin filler is filled inside the trench portions, stress generated on the side walls of the trench portions, for example, is absorbed by the flexible resin filler. Thus, even if capacitance is enlarged by forming trench portions (recessed portions) at a narrow pitch, cracks do not occur on the side walls of the trench portions.

Furthermore, by arranging a conductive portion to cover resin filler in the trench portions, thermal expansion of the resin filler is suppressed, and stress exerted on a via conductor, for example, is mitigated, and line breakage or the like of the via conductor is suppressed.

In a printed wiring board according to another embodiment of the present invention, since an electronic component having a high-capacitance capacitor section is accommodated in a position directly under a mounted IC chip, the distance is reduced between the IC chip and the capacitor section, and the power supply to the IC chip is intensified. Therefore, even if an increase in power consumption occurs instantaneously in a high-frequency IC chip, the voltage supply does not fall off, thus allowing the IC chip to continue operating properly.

In a printed wiring board according to another embodiment of the present invention, since an IC chip is mounted directly on an electronic component having a high-capacitance capacitor section, the distance is reduced between the IC chip and the capacitor section, and the power supply to the IC chip is intensified. Therefore, even if an increase in power consumption occurs instantaneously in a high-frequency IC chip, the voltage supply does not fall off, thus allowing the IC chip to continue operating properly.

Obviously, numerous modifications and variations of the present invention are possible in light of the above teachings. It is therefore to be understood that within the scope of the appended claims, the invention may be practiced otherwise than as specifically described herein.

What is claimed is:

1. An electronic component, comprising:
a substrate having a surface and at least one trench portion opening on the surface;
a capacitor portion comprising a lower electrode formed on the surface of the substrate and on a wall surface of the trench portion, a dielectric layer formed on the lower electrode, and an upper electrode formed on the dielectric layer;
a resin filler filling a space inside the trench portion lined by the upper electrode;
an insulation layer formed on the surface of the substrate;
a conductive portion formed on the insulation layer and positioned to cover the trench portion; and
a via conductor connecting the conductive portion and one of the lower electrode and the upper electrode.

2. The electronic component according to claim 1, wherein the conductive portion forms a land portion of the via conductor.

3. The electronic component according to claim 1, wherein the one of the lower electrode and the upper electrode is connected to the via conductor in a region of the substrate where the trench portion is not formed.

4. The electronic component according to claim 1, wherein the resin filler and the insulation layer are made of a same material.

5. The electronic component according to claim 1, wherein the insulation layer comprises a photosensitive resin.

6. The electronic component according to claim 1, wherein the insulation layer is made of a photosensitive resin.

7. The electronic component according to claim 1, wherein the substrate is made of one of silicon, a glass and a ceramic.

8. The electronic component according to claim 1, wherein the lower electrode has a step portion on a periphery portion of an opening of the trench portion.

9. The electronic component according to claim 1, wherein the capacitor portion has a rounded thicker portion on a periphery portion of an opening of the trench portion.

10. The electronic component according to claim 1, wherein the substrate has the at least one trench portion in a plurality.

11. A method for manufacturing an electronic component, comprising:
forming at least one trench portion in a substrate such that the trench portion has an opening on a surface of the substrate;
forming on the surface of the substrate and a wall portion of the trench portion a capacitor portion comprising a lower electrode, a dielectric layer and an upper electrode;
filling a resin filler in a space inside the trench portion lined by the upper electrode;
forming an insulation layer on the surface of the substrate;
forming a conductive portion on the insulation layer such that the conductive portion covers the trench portion; and
forming a via conductor in the insulation layer such that the conductive portion is connected to one of the lower electrode and the upper electrode.

12. The method for manufacturing an electronic component according to claim 11, wherein the forming of the capacitor portion comprises forming the lower electrode on the surface of the substrate and on the wall surface of the trench portion, forming the dielectric layer on the lower electrode, and forming the upper electrode on the dielectric layer.

13. The method for manufacturing an electronic component according to claim 11, wherein the resin filler and the insulation layer comprises a same material.

14. The method for manufacturing an electronic component according to claim 11, wherein the resin filler and the insulation layer are made of a same material.

15. The method for manufacturing an electronic component according to claim 11, wherein the insulation layer comprises a photosensitive resin.

16. The method for manufacturing an electronic component according to claim 11, wherein the insulation layer made of a photosensitive resin.

17. The method for manufacturing an electronic component according to claim 11, wherein the forming of the capacitor portion comprises forming a step portion in the lower electrode on a periphery portion of the opening of the trench portion.

18. The method according to claim 11, wherein the forming of the capacitor portion comprises forming a rounded thicker portion in the capacitor on a periphery portion of the opening of the trench portion.

19. The method for manufacturing an electronic component according to claim 11, further comprising removing a portion of the dielectric layer by using the insulation layer as a mask.

20. The method for manufacturing an electronic component according to claim 11, wherein the forming of the at least one trench comprises forming the trench in a plurality.
